(19) United States
(12) Patent Application Publication
(10) Pub. No.: US 2005/0230724 A1
(43) Pub. Date: Oct. 20, 2005

(54) 3D cross-point memory array with shared connections

(75) Inventor: Sheng Teng Hsu, Camas, WA (US)

Correspondence Address: ROBERT D. VARITZ, 4915 S.E. 33RD PLACE, PORTLAND, OR, 97202, US

(73) Assignee: Sharp Laboratories of America, Inc.

(21) Appl. No.: 10/825,830

(22) Filed: Apr. 16, 2004

(51) Int. Cl. H01L 31/113

(52) U.S. Cl. 257/295

(57) ABSTRACT

A 3D cross-point memory array is provided having current sensing devices connected the bit line for reading out the bit value. The 3D cross-point memory array may be configured as multiple resistive memory array layers. Electrodes, either bit lines or word lines, may be connected together between resistive memory array layers.

### BACKGROUND OF THE INVENTION

This invention relates to a nonvolatile cross-point memory array, and more particularly to a cross point structure utilizing electric pulse induced resistance change effects and methods of detecting the resistance change.

The patent application entitled, Electrically Programmable Resistance Cross Point Memory Sensing Method, filed on Mar. 3, 2004, invented by Sheng Teng Hsu, application Ser. No. 10/794,308, is hereby incorporated herein by reference. Use of a low input impedance current sensing devices was taught for allowing multiple resistive bits within a cross-point array to share a single bit line, without excessive read interference from unselected bits.

U.S. Pat. No. 6,569,745, entitled Shared Bit Line Cross Point Memory Array, invented by Sheng Teng Hsu and issued on May 27, 2003, is hereby incorporated herein by reference. A method of sharing a each bit line with two adjacent word lines was taught, along with methods of manufacturing the memory array.

### BRIEF DESCRIPTION OF THE DRAWINGS

FIG. 1 is an isometric view of a cross point memory array area with a shared bit line.

FIG. 2 is a schematic view of a two level resistive memory array structure with a shared bit line.

FIG. 3 is a schematic view of a two level resistive memory array structure with a shared word line.

FIG. 4 is a cross-sectional view of a two level resistive memory array structure.

FIG. 5 is a cross-sectional view of two sets of two level resistive memory array structures with middle electrodes connected by a via.

FIG. 6 is a cross-sectional view of a memory structure during processing.

FIG. 7 is a cross-sectional view of a memory structure during processing.

FIG. 8 is a top view of a memory structure during processing.

FIG. 9 is a cross-sectional view of a memory structure during processing.

FIG. 10 is a top view of a memory structure during processing.

FIG. 11 is a cross-sectional view of a memory structure during processing.

FIG. 12 is a cross-sectional view of a memory structure during processing.

FIG. 13 is a cross-sectional view of a memory structure during processing.

FIG. 14 is a cross-sectional view of a memory structure during processing.

FIG. 15 is a cross-sectional view of a memory structure during processing.

### DETAILED DESCRIPTION OF THE INVENTION

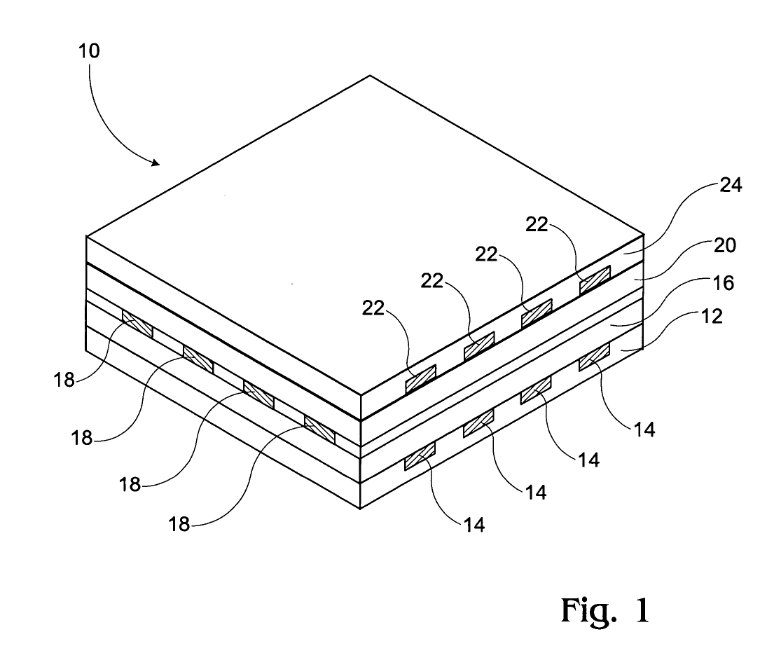

FIG. 1 is an isometric drawing illustrating a shared middle electrode cross point memory array area 10. An embodiment of the memory array area 10 comprises a substrate 12 with a plurality of bottom electrodes 14 formed thereon. A layer of oxide 16 overlies the substrate 12 and bottom electrodes 14. A plurality of middle electrodes 18 overly the layer of oxide 16. A second layer of oxide 20 overlies the plurality of middle electrodes 18. A plurality of top electrodes 22 overly the second layer of oxide 20. A passivation layer 24 overlies the plurality of top electrodes 22. As is apparent from the isometric view, a cross point configuration is formed between the bottom electrodes and the middle electrodes, as well as, between the top electrodes and the middle electrodes. In an embodiment of the memory array, the plurality of middle electrodes 18 acts as bit lines, while the plurality of bottom electrodes acts a first layer of word lines, and the plurality of top electrodes acts as a second layer of word lines. In this way two sets of word lines share a single set of bit lines. In a low cross talk version, the layer of oxide 16 would be etched so that a perovskite material could be deposited connecting the plurality of bottom word lines 14 to the plurality of bit lines 18 at each cross point. A similar structure could be formed between the bit lines and the plurality of top word lines. Alternatively, continuous active regions could be used in place of the layer of oxide 16 and the second layer of oxide 20.

In an alternative embodiment the plurality of middle electrodes acts as a set of word lines, while the plurality of top electrodes and the plurality of bottom electrodes each act as a set of bit lines. In this case, if a read voltage is applied to one of the plurality of word lines, the appropriate bits will be read out of through the plurality of top electrodes, and the plurality of bottom electrodes essentially simultaneously.

Note that the terms “top”, “middle”, and “bottom” are for ease of explanation with respect to the drawings and should not be construed as requiring a specific orientation. The device can assume any spatial orientation during manufacture and operation.

FIG. 1 shows just the memory array area. It should be clear that in an actual device, the substrate 12, the bottom electrodes 14, the middle electrodes 18, and the top electrodes 22 may extend well beyond the memory array area to other areas containing other device structures.

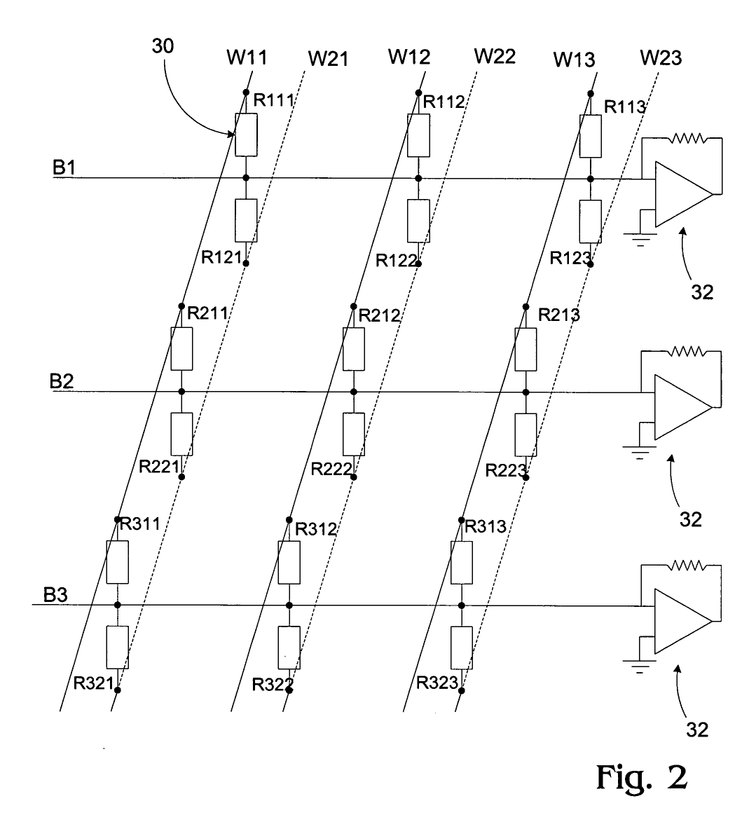

FIG. 2 is a schematic view of a cross-point one resistor memory array showing two layers, with each layer having 3 by 3 one resistor memory array. Word lines may be designated by Wnm, where n represents the level, and m represents the word line. Bit lines are designated by Bu, where u represents the bit number. Each resistive bit 30 is designated by Runm. Word line W11 is the first word line on the first level and is connected to multiple bits designated Ru11. Similarly, word line W21 is the first word line on the second level and is connected to multiple bits designated Ru21. So bit R111 is connected between the word line W11 and bit line B1, while bit R121 is connected between the word line W21 and the bit line B1. Each bit line is connected to a current sensing device 32, which is represented by a simple op amp configured in a current sensing, or transimpedance, mode. The current sensing device may be an op amp, an odd stage cascade inverter, a differential amplifier or simple CMOS current sensor, for example.

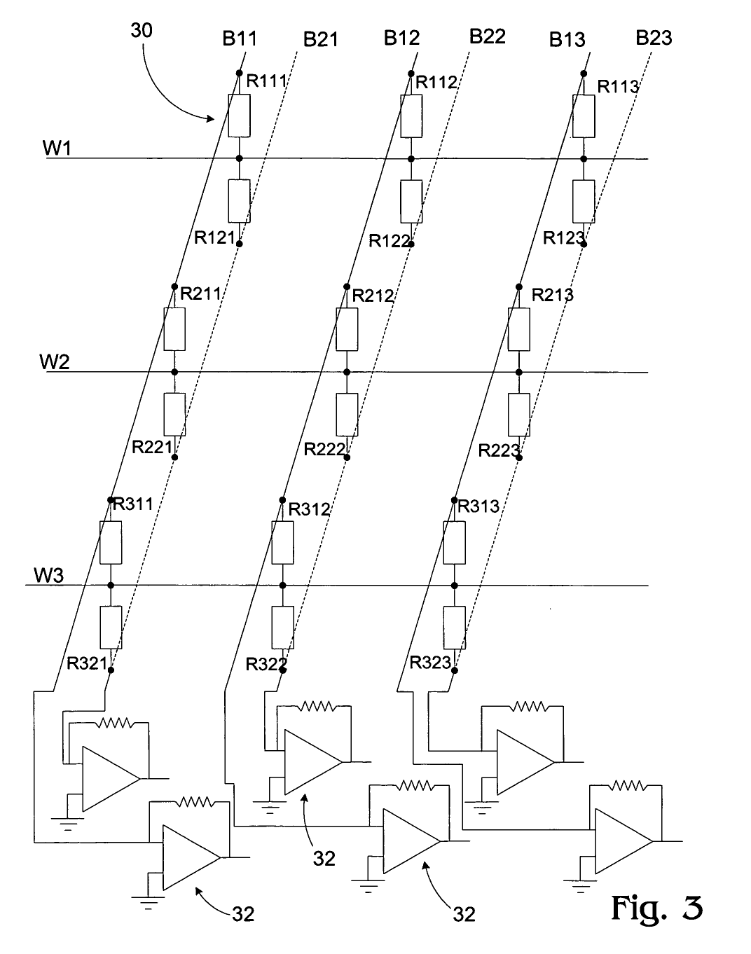

As described above, in an alternative embodiment, a single word line could access two levels of bit lines. FIG. 3 is a schematic view of an alternative cross-point one resistor memory array showing two layers, with each layer having 3 by 3 one resistor memory array. Bit lines may be designated by Bnm, where n represents the level, and m represents the bit line. Word lines are designated by Wu, where u represents the word line number. Each resistive bit 30 is designated by Runm. Bit line B11 is the first bit line on the first level and is connected to multiple bits designated Ru11. Similarly, bit line B21 is the first bit line on the second level and is connected to multiple bits designated Ru21. So bit R111 is connected between the word line W1 and bit line B11, while bit R121 is connected between the word line W1 and bit line B21. Each bit line is connected to a current sensing device 32.

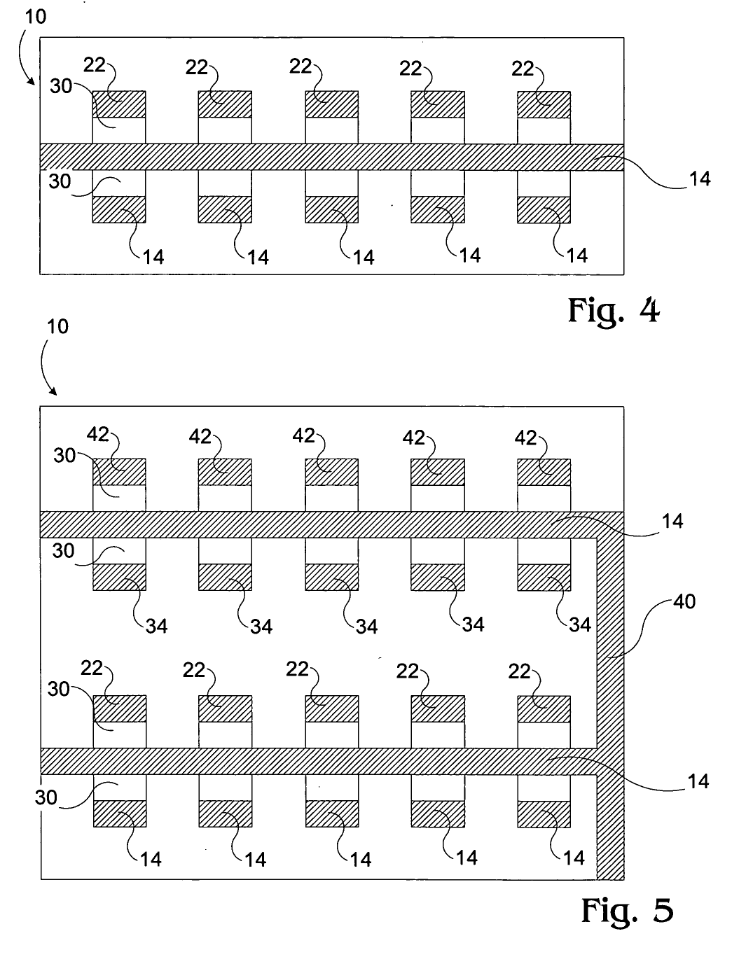

FIG. 4 shows a cross-sectional view of a cross-point memory array 10 with a shared middle electrode 18, taken along the middle electrode. A first set of bottom electrodes 14 and a first set of top electrodes are connected to the middle electrode 18 through resistive bits 30.

FIG. 5 shows a cross-sectional view of a cross-point memory array with a first middle electrode 18, taken along the middle electrode. A first set of bottom electrodes 14 and a first set of top electrodes 22 are connected to the first middle electrode 18 through resistive bits 30. A second level of the memory array is also shown. The second level comprises a second middle electrode 38. A second set of bottom electrodes 34 and a second set of top electrodes 42 are connected to the second middle electrode 38 through resistive bits 30. As shown the first middle electrode 18 and the second middle electrode 34 are connected together through a via 40.

In an embodiment of the present memory array, the first middle electrode 18 and the second middle electrode 38 act as shared bit lines connected together by the via 40. In this way, bits can be read by current sensing devices (not shown) connected to the bit lines, by selecting any word line at any level within the memory array structure, where the sets of top electrodes and the sets of bottom electrodes act as word lines.

In an alternative embodiment of the present memory array, the middle electrode 18 and the second middle electrode 38 act as shared word lines connected together by the via 40. In this way, bits can be read by applying a read voltage to a single word line, and then reading bit lines from multiple levels within the memory array structure, where the sets of top electrodes and the sets of bottom electrodes act as bit lines.

In an alternative embodiment, the first middle electrode 18 and the second middle electrode 38 are not connected by a via 40. Each set of bits, comprising two layers of bits connected to a middle electrode would then operate as separate memory arrays. These memory arrays could still be stacked as shown to optimize packing density. In another embodiment, a set of bits may comprise a single layer of bits.

The various embodiments and configurations of memory arrays described above could be selected, mixed and matched by one of ordinary skill in the art in the course of designing a memory structure as desired, such that a hybrid memory structure incorporating one or more embodiments could be constructed.

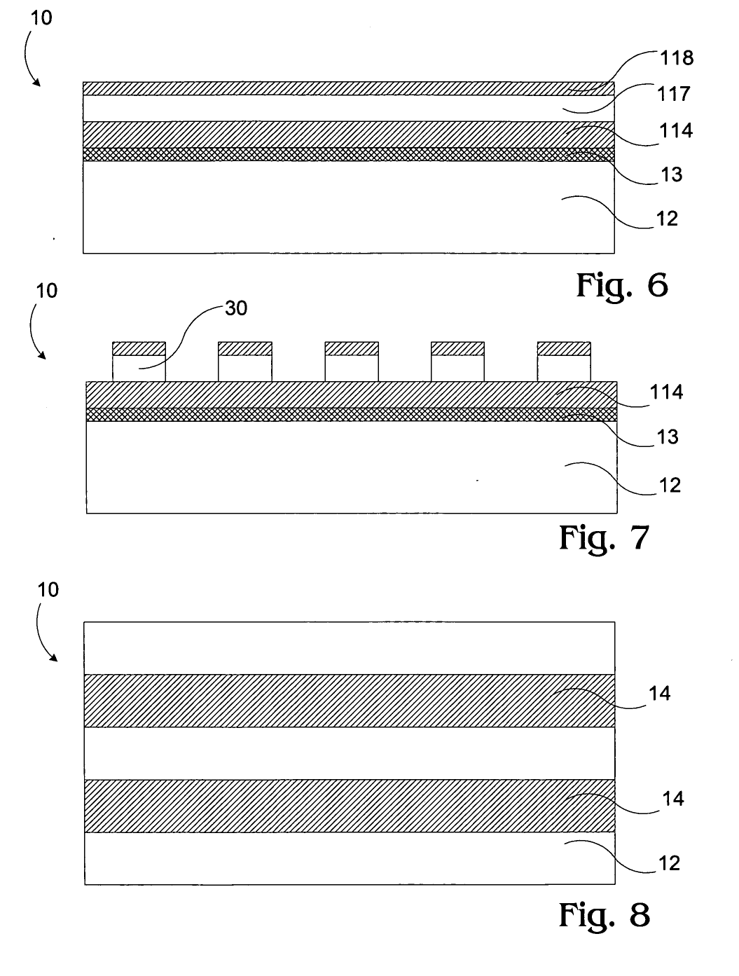

A method of forming a multi-level resistive memory array is provided. FIG. 6 shows a cross-sectional view of a cross point memory array area 10 following some initial processing. Fabrication of peripheral circuitry, including current sensing devices, which are to be connected to the bit lines, may be formed prior to forming the memory array. In an embodiment of the present memory array structure, some of the circuitry is formed below the region upon which the memory array will be formed. The memory array area 10 comprises a substrate 12, possibly including peripheral circuitry (not shown), is provided. A layer of silicon oxide 13 is deposited overlying the substrate and planarized. In an embodiment of the present method, the silicon oxide layer is between approximately 100 nm and 200 nm and is planarized using CMP. A first bottom electrode material 114 is deposited, followed by a resistive memory material 117, a metal layer 118, and a hard mask (not shown).

The substrate 12 is any suitable substrate material, whether amorphous, polycrystalline or crystalline, such as LaMO₃, Si, SiO₂, TiN or other material.

The bottom electrode material 114 is made of a conductive material, including conductive oxides. In a preferred embodiment, the conductive material is a material, such as YBa₂Cu₃O₇ (YBCO), that allows the epitaxial growth of an overlying perovskite material. In another preferred embodiment, the conductive material is platinum or iridium.

The resistive memory material 117 a material capable of having its resistivity changed in response to an electrical signal. The resistive memory material is preferably a perovskite material, such as a colossal magnetoresistive (CMR) material or a high temperature superconducting (HTSC) material, for example a material having the formula Pr₁₋ₓCaₓMnO₃ (PCMO), such as Pr_{0.7}Ca_{0.3}MnO₃. Another example of a suitable material is Gd₁₋ₓCaₓBaCo₂O₅₊₅, for example Gd_{0.7}Ca_{0.3}BaCo₂O₅₊₅. The resistive memory material 117 can be deposited using any suitable deposition technique including pulsed laser deposition, rf-sputtering, e-beam evaporation, thermal evaporation, metal organic deposition, sol gel deposition, and metal organic chemical vapor deposition.

The metal layer 118 will form the top electrode. In an embodiment of the present method, the metal layer will initially be deposited to half the thickness desired for the top electrode. The metal layer 118 comprises a conductive material, preferably YBCO, platinum, iridium, copper, silver, or gold.

The hard mask may be any suitable material, such as TiN, SiN, or SiO₂.

Photoresist is applied and patterned. A dry etch is used to etch the hard mask, metal layer 118 and resistive memory material 117 stopping at the bottom electrode material 114, as shown in FIG. 7. In an embodiment of the present method, this etching process will produce resistive memory bits 30 as discrete posts.

Photoresist is then applied and patterned. The bottom electrode material 114 is then etched to form bottom electrodes 14, as shown in the top view of FIG. 8.

In an alternative embodiment, the first patterning and etching step will produce strips of resistive memory material 117 and metal layer 118. Photoresist would then be applied and patterned and the second etch process would etch through the metal layer 118, resistive memory material 117 and the bottom electrode material 114, to form bottom electrodes 14, as shown in the top view of FIG. 8. The resistive memory bits would then be discrete posts. This alternative embodiment may provide for self-alignment of the resistive memory bits with the bottom electrodes 14.

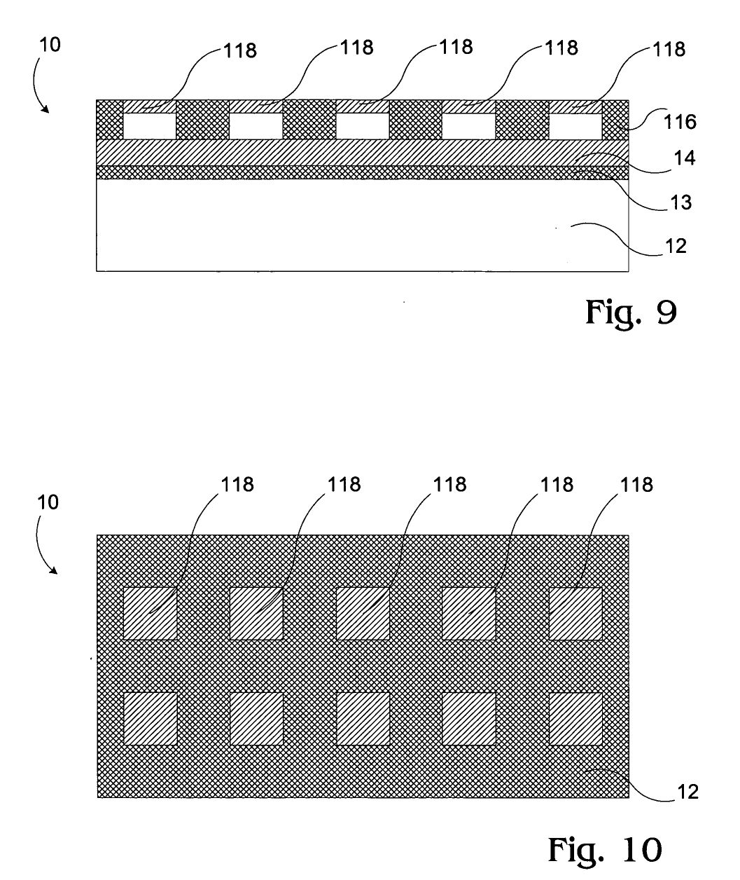

A layer of silicon oxide 116 is deposited and planarized. The hard mask may be removed prior to depositing the layer of silicon oxide, or the hard mask may be removed by the planarization process. The planarization stops at the metal layer 118, as shown in FIG. 9. In an embodiment of the present method, the silicon oxide is deposited to a thickness of approximately 1.5 times the combined thickness of the bottom electrode material 114, the resistive memory material 117 and the metal layer; and planarized using CMP.

FIG. 10 shows a top view of the memory array 10 following deposition of the layer of silicon oxide 116 and planarization. The resistive memory bits are discrete posts topped with metal layer 118.

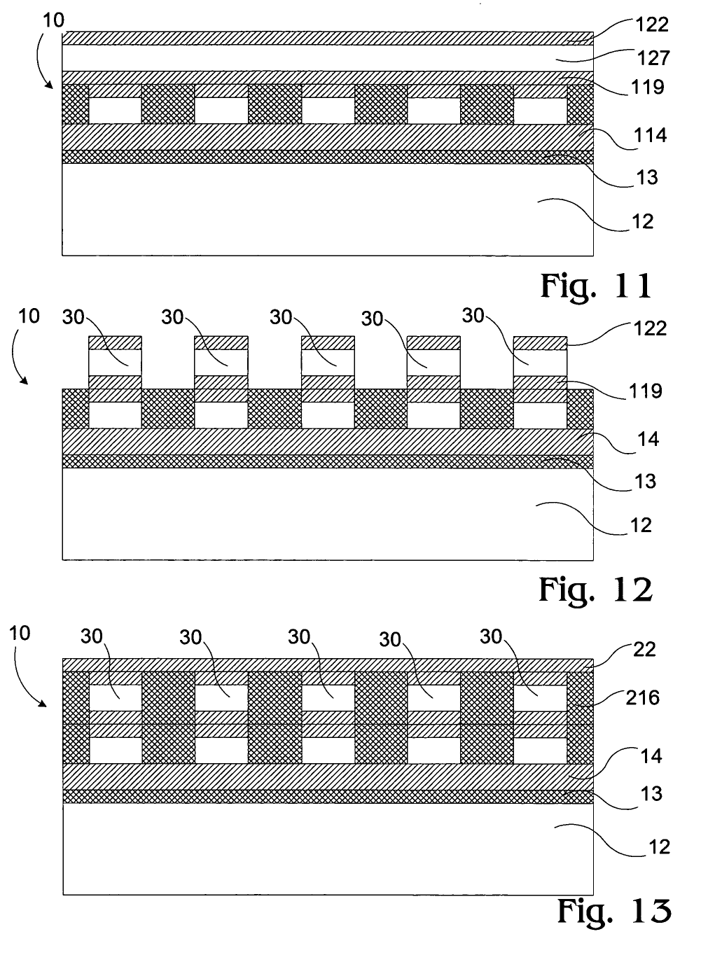

A shown in FIG. 11, another layer of metal 119 is deposited along with a resistive memory material 127, and a top metal layer 122. A hard mask (not shown) may also be deposited.

The steps of depositing photoresist and patterning are then repeated, although the patterns are repositioned so that the layer of metal 119 will form electrodes that are at a different angle than bottom electrodes 14; possibly orthogonal to the bottom electrodes 14. This process results in a second layer of resistive memory bits 30 formed as discrete posts, as shown in FIG. 12.

As shown in FIG. 13, a second layer of silicon oxide 216 has been deposited and planarized. Another metal layer is deposited and patterned to complete the top electrodes 22. This process has produced a first set of resistive memory bits comprising two layers of resistive memory bits connected to shared, middle electrodes.

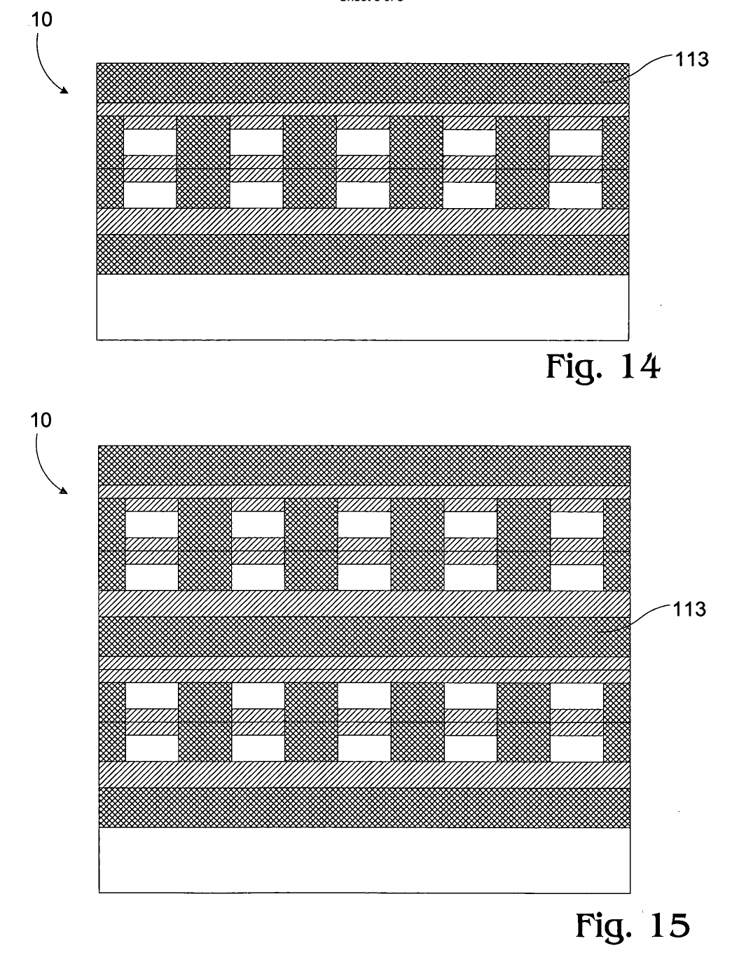

As shown in FIG. 14, a layer of silicon oxide 113 may then be deposited overlying the first set of memory bits and planarized. In an embodiment of the present method, the silicon oxide layer is between approximately 100 nm and 200 nm and is planarized using CMP. The process of forming a set of resistive memory bits connected in a cross-point array may then be performed to produce a multi-level memory array as shown in FIG. 15. This process can be repeated as desired to produce a stack of cross-point memory arrays.

In an alternative embodiment, each set of resistive memory bits may be formed using embodiments of the process steps as taught by U.S. Pat. No. 6,569,745.

As discussed in connection with FIG. 5, multiple middle electrodes may be connected together by vias to function as either shared bit lines, or shared word lines to share peripheral circuitry, as desired.

Although a preferred embodiment, and other embodiments have been discussed above, the coverage is not limited to these specific embodiments. Rather, the claims shall determine the scope of the invention.

1. A memory structure comprising;
a) a substrate;
b) a plurality of bottom electrodes overlying the substrate;
c) a plurality of top electrodes overlying the plurality of bottom electrodes;
d) a plurality of middle electrodes interposed between the plurality of bottom electrodes and the plurality of top electrodes, wherein each middle electrode forms a cross point with each bottom electrode and each top electrode as it crosses between the top electrode and the bottom electrode;
e) a first resistive memory material interposed between the plurality of bottom electrodes and the plurality of middle electrodes at each cross point;
f) a second resistive memory material interposed between the plurality of top electrodes and the plurality of middle electrodes at each cross point; and
g) a plurality of current sensing devices connected to the plurality of top electrodes, the plurality of bottom electrodes, or the plurality of middle electrodes.

2. The memory structure of claim 1, wherein the plurality of bottom electrodes comprise a bottom electrode material that allows for epitaxial formation of the perovskite material overlying the plurality of bottom electrodes.

3. The memory structure of claim 1, wherein the bottom electrode material is YBCO.

4. The memory structure of claim 1, wherein the bottom electrode material is platinum or iridium.

5. The memory structure of claim 1, wherein the first resistive memory material is a colossal magnetoresistance (CMR) material.

6. The memory structure of claim 1, wherein the first resistive memory material is Pr₁₋ₓCaₓMnO₃ (PCMO).

7. The memory structure of claim 1, wherein the first resistive memory material is Gd₁₋ₓCaₓBaCo₂O₅₊₅.

8. The memory structure of claim 1, wherein the plurality of current sensing devices is connected the plurality of middle electrodes, whereby the middle electrodes serve as shared bit lines.

9. The memory structure of claim 1, wherein the plurality of current sensing devices is connected to the plurality of top electrodes and the plurality of bottom electrodes and the plurality of middle electrodes serve as shared word lines.

10. A method of manufacturing a memory structure comprising the steps of:
a) providing a substrate;
b) depositing and planarizing a silicon oxide layer overlying the substrate;
c) depositing electrode material over the silicon oxide layer;
d) depositing resistive memory material, and a second electrode material overlying the electrode material;
e) patterning the second electrode material and the resistive memory material, stopping at the electrode material;
f) patterning the electrode material to form electrodes having a first orientation;
g) depositing silicon oxide and planarizing the silicon oxide stopping at the second electrode material;
h) depositing a electrode material; and
i) repeating steps (d) through (g), wherein step (f) patterning the electrode material forms electrodes at a second orientation, whereby a first two layer resistive memory array is formed.

11. The method of claim 10, further comprising repeating steps (b) through (i) to form a second two layer resistive memory array above the first two layer resistive memory array.

12. The method of claim 10, wherein the silicon oxide layer is between approximately 100 nm and 200 nm thick.

13. The method of claim 10, wherein the electrode material is YBCO.

14. The method of claim 10, wherein the electrode material is platinum or iridium.

15. The method of claim 10, wherein the resistive memory material is a perovskite material.

16. The method of claim 15, wherein the perovskite material is a colossal magnetoresistance (CMR) material.

17. The method of claim 16, wherein the perovskite material is Pr₁₋ₓCaₓMnO₃ (PCMO).

18. The method of claim 16, wherein the perovskite material is Gd₁₋ₓCaₓBaCO₂O₅₊₅.

19. The method of claim 10, wherein the step of planarizing the silicon oxide in step (g) comprises chemical mechanical polishing.

20. The method of claim 10, wherein first orientation and the second orientation produce electrodes arranged as a cross-point array.

21. The method of claim 10, further comprising forming peripheral circuitry prior to step (a).

22. The method of claim 11, further comprising forming vias to connect at least one electrode from the second two layer resistive memory array to at least one electrode from the first two layer resistive memory array.

23. The method of claim 22, wherein the connected electrodes form a common bit line.

24. The method of claim 22, wherein the connected electrodes form a common word line.
